(19) United States
(12) Patent Application Publication
(10) Pub. No.: US 2016/0061921 A1
(43) Pub. Date: Mar. 3, 2016

(54) AMIDE PROTON TRANSFER (APT) AND ELECTRIC PROPERTIES TOMOGRAPHY (EPT) IMAGING IN A SINGLE MR ACQUISITION

(71) Applicant: KONINKLIJKE PHILIPS N.V., Eindhoven (NL)

(72) Inventors: ULRICH KATSCHER, EINDHOVEN (NL); MARIYA IVANOVA DONEVA, EINDHOVEN (NL); CHRISTIAN STEHNING, EINDHOVEN (NL); JOHAN SAMUEL VAN DEN BRINK, EINDHOVEN (NL); JOCHEN KEUPP, EINDHOVEN (NL)

(21) Appl. No.: 14/780,581

(22) PCT Filed: Mar. 26, 2014
(86) PCT No.: PCT/EP2014/056018

§ 371 Date: Sep. 28, 2015

Related U.S. Application Data
(60) Provisional application No. 61/806,432, filed on Mar. 29, 2013.

(30) Foreign Application Priority Data
May 2, 2013 (EP) 13166255.3

(51) Int. Cl. G01R 33/56; G01R 33/48

(52) U.S. Cl. CPC G01R 33/5605; G01R 33/4828

(57) ABSTRACT

The present invention relates to a magnetic resonance imaging, MRI, system (200) for acquiring magnetic resonance data from a target volume in a subject (218), the MRI system (200) comprising a memory (236) for storing machine executable instructions; and a processor (230) for controlling the MRI system (200), wherein execution of the machine executable instructions causes the processor (230) to use a first MRI sequence (401) containing a first selective RF pulse (413) followed by a first excitation RF pulse (415) to control the MRI system (200) to selectively excite and saturate exchangeable amide protons within a first frequency range in the target volume; irradiate said target volume with the first excitation RF pulse (415) that is adapted to excite bulk water protons in the target volume; and acquire first magnetic resonance imaging data from the target volume in response to the first excitation RF pulse (415); use a second MRI sequence (403) containing a second selective RF pulse (423) followed by a second excitation RF pulse (425) to control the MRI system (200) to selectively excite and saturate the exchangeable amide protons within a second frequency range in the target volume; irradiate said target volume with the second excitation RF pulse (425) that is adapted to excite said bulk water protons; and acquire second magnetic resonance imaging data from said target volume in response to the second excitation RF pulse (425); wherein the first MRI sequence (401) comprises gradients (417) having first gradient polarities reverse of second gradient polarities (427) of the second MRI sequence (403).

### TECHNICAL FIELD OF THE INVENTION

The invention relates to magnetic resonance imaging, in particular to a method for combining APT and EPT in a single MR acquisition.

### BACKGROUND OF THE INVENTION

Amide proton transfer (APT) and Electric Properties Tomography (EPT) have emerged as new methods to quantitatively investigate the biochemistry of tissue. APT is based on the asymmetry of the magnetization transfer (MT) frequency shift relative to water resonance frequency and reflects the concentration of amide containing proteins. EPT is based on the curvature of the measured transceive phase of a TSE or bFFE image and reflects the electric conductivity of the tissue.

Voigt T et al., MRM 66 (2011) 456 discloses a method for quantitative conductivity and permittivity imaging of the human brain using EPT.

J. Zhou et al., MRM 50:1120-1126 (2003) discloses an APT contrast method for imaging of brain tumors.

### SUMMARY OF THE INVENTION

Various embodiments provide for an improved method of operating a magnetic resonance imaging MRI system, an improved computer program product and an improved magnetic resonance imaging MRI system as described by the subject matter of the independent claims. Advantageous embodiments are described in the dependent claims.

In one aspect, the invention relates to a magnetic resonance imaging, MRI, system for acquiring magnetic resonance data from a target volume in a subject, the MRI system comprising a memory for storing machine executable instructions; and a processor for controlling the MRI system, wherein execution of the machine executable instructions causes the processor to:
a. use a first MRI sequence containing a first selective RF pulse followed by a first excitation RF pulse to control the MRI system to selectively excite and saturate exchangeable amide protons within a first frequency range in the target volume; irradiate said target volume with the first excitation RF pulse that is adapted to excite bulk water protons in the target volume; and acquire first magnetic resonance imaging data from the target volume in response to the first excitation RF pulse;
b. use a second MRI sequence containing a second selective RF pulse followed by a second excitation RF pulse to control the MRI system to selectively excite and saturate the exchangeable amide protons within a second frequency range in the target volume; irradiate said target volume with a second excitation RF pulse that is adapted to excite said bulk water protons; and acquire second magnetic resonance imaging data from said target volume in response to the second excitation RF pulse;
wherein the first MRI sequence comprises gradients having first gradient polarities reverse of second gradient polarities of the second MRI sequence;
c. use a third MRI sequence to control the MRI system to acquire un-saturated MRI data of the target volume;
d. generate from the first MRI and second MRI data a respective first phase and second phase distributions;
e. use the first and second phase distributions for determining an electrical conductivity distribution of the target volume;
f. use the first, second and un-saturated MRI data for determining a magnitude distribution of amide proton transfer, APT, corresponding to the transfer of saturation between the amide protons and the water protons.

The first, second and third MRI pulse sequences may be turbo spin echo TSE sequences. The third MRI pulse sequence does not contain selective (saturation) RF pulses. The first, second and third MRI data may be acquired in a same scan. The first and second selective RF pulses are used to saturate spins at a certain chemical shift (offset) position with respect to the water proton frequency.

Beyond the disclosed combination of amide proton transfer(APT) MR imaging with electrical properties tomography, a further aspect of the invention is to apply chemical exchange saturation transfer (CEST) magnetic resonance imaging with electric properties tomography. CEST exploits the ability of Nuclear Magnetic Resonance (NMR) to resolve different signals arising from protons on different molecules. By selectively saturating a particular proton signal (associated with a particular molecule or exogenous CEST agent) that is in exchange with surrounding water molecules, the MRI signal from the surrounding bulk water molecules is also attenuated. Images obtained with and without the RF saturating pulse reveal the location of the CEST agent. The chemical exchange must be in the intermediate regime where exchange is fast enough to efficiently saturate the bulk water signal but slow enough that there is a chemical shift difference between the exchangeable proton and the water proton resonances. The magnitude of the CEST effect therefore depends on both the exchange rate and the number of exchangeable protons. A variant of the CEST technique, known as PARACEST, may be much more sensitive than traditional molecular imaging techniques and should be able to detect nanomolar concentrations. PARACEST typically relies on water exchange between the bulk water and water bound to paramagnetic Lanthanide complexes. Saturation of the Lanthanide ion bound water resonance leads to attenuation of the bulk water signal via water exchange. The large paramagnetic chemical shift of the bound water molecules allows them to tolerate much faster exchange rates with the bulk water while still remaining in the intermediate exchange regime, thereby providing much more efficient saturation of the bulk water signal and much greater CEST sensitivity.

An insight of the present invention is that only minor adaptations to CEST MR data acquisition sequences are required to enable to extract information on the electrical properties of the tissue being examined. Notably, the CEST MR data acquisition involves several, typically about seven, scans with and without selective saturation of the CEST contrast agent. From these acquired MR data, the spectral asymmetry and spatial main magnetic field inhomogeneity can be derived. Among these CEST MR data acquisitions essentially only the spectral content varies via the image magnitude, but have common image phase content. Hence, from an average of these CEST MR data, the spatial distribution of the electrical properties can be reconstructed similarly to the electrical properties tomography method that is known per se from IEEE Trans. Med. Imag. 28(2009)1365. Further, the averaging of the CEST MRI data lead to an improved signal-to-noise ratio of the reconstructed electrical properties tomography image. CEST MR images and electrical properties tomography images provide complementary diagnostically relevant information, notably in oncology.

According to one embodiment, field-echo based sequences are used instead spin-echo based sequences. MRI data for different saturation frequencies are acquired applying different echo times, allowing an intrinsic estimation of a B₀-map which represents the spatial variations of the stationary main magnetic field without additional scan time. Such an intrinsic estimation of the B₀-map in an Amide Proton Transfer MRI approach is known per se from Jochen Keupp, Holger Eggers, Intrinsic Field Homogeneity Correction in Fast Spin Echo Based Amide Proton Transfer MRI, ISMRM 20 (2012) 4185) by Jochen Keupp, Holger Eggers. This B₀-map can be used to remove the phase contribution arising from B0 inhomogeneities, which are unwanted for EPT reconstruction, and which occur in phase maps if field-echo based sequences are used instead spin-echo based sequences. The aforementioned concept of switching gradient polarization to remove unwanted phase contributions from eddy-currents is identical for field-echo and spin-echo based sequences. Preferably, the same echo time is used for different gradient polarizations. Alternatively, a separate B0-map (commonly acquired for APT) can be used for this purpose.

The first and second frequency range may not be overlapping with a resonance frequency of bulk water protons.

These features may be advantageous as they may reduce the scanning time of a medical device that performs both the APT and electrical properties tomography EPT measurements.

Another advantage may be that the SNR is enhanced for EPT measurements as they are averaged over multiple acquired MRI data.

Another advantage may be that the asymmetric phase effect due to eddy currents may be removed by repeating the same sequence with inverted gradient polarities and averaging the resulting phase distributions.

According to one embodiment, the determination of the electrical conductivity distribution comprises: averaging the first phase distribution and second phase distributions for obtaining an averaged phase distribution; determining from the averaged phase distribution a B1 field phase distribution for determining the electrical conductivity distribution. This may be advantageous as it may provide an accurate estimation of the EPT distribution based on an average value. The mean B1 phase values were computed on a voxel-by-voxel basis across the two distributions.

According to one embodiment, the determination of the electrical conductivity distribution comprises: generating from the un-saturated MRI data a third phase distribution; averaging the first, second and third phase distributions for obtaining an averaged phase distribution; determining from the averaged phase distribution a B1 field phase distribution for determining the electrical conductivity distribution. This may further increase the SNR of the EPT distributions as it is determined using additional sequences (i.e. third MRI data).

According to one embodiment, the MRI system further comprises multiple RF coils for parallel data acquisition, the multiple RF coils having a spatial sensitivity map determined using pre-acquired k-space data, wherein the execution of the machine executable instructions further causes the processor to reconstruct image data from the acquired first, second and third MRI data using the sensitivity map. This may be advantageous as it may further reduce the scanning time.

According to one embodiment, the first MRI data and second MRI data are acquired using a predefined first and second k-space region respectively, wherein the second k-space region is part of the first k-space region. For example, a keyhole imaging may be used.

According to one embodiment, the second k-space region is the central region of k-space. These embodiments may be advantageous as they may further reduce the scanning time by limited data acquisition without a loss of spatial resolution. This partial acquisition may be motivated by the fact that most of the contrast is determined by the k-space center. And, the fact that high spatial frequency content of the k-space may be constant in time so that it is unnecessary to be updated. For example, the high spatial frequency data may be acquired at once using the first MRI sequence.

According to one embodiment, the first and second frequency range are symmetrically shifted on opposite sides of the water resonance frequency.

According to one embodiment, the center of first frequency range is set to a resonance frequency of the amide protons. For example, the first and the second frequency ranges may be respectively centered around +3.5 ppm and −3.5 ppm from the water resonance frequency.

According to one embodiment, the first gradient polarities comprise slice-selective, read, and phase encoding gradient polarities. The second gradient polarities also comprise slice-selective, read, and phase encoding gradient polarities.

According to one embodiment, the magnitude of amide proton transfer is determined using an amide proton transfer ratio MTR at the first frequency range and at the second frequency range.

According to one embodiment, the first and second MRI data form a first pair of MRI data, wherein the execution of the machine executable instructions further causes the processor to repeat step a) and step b) for acquiring multiple pairs of MRI data using pulse sequences having mutually inverted polarities, wherein the determination of the magnitude of amide proton transfer, APT, comprises determining for each pair a respective APT distribution, and averaging the determined APT distributions for obtaining an averaged APT distribution.

For example, the multiple pairs comprise three pairs of MRI data acquired using three pairs of pulse sequences, each containing a selective RF pulse followed by an excitation RF pulse to control the MRI system to selectively excite and saturate exchangeable amide protons within a frequency range that is centered around ±3, ±3.5, and ±4 ppm from the water resonance frequency respectively.

The four extra offsets around ±3.5 ppm were acquired and may be used to correct for the artifacts that may be caused by BO inhomogeneity.

The electrical conductivity distribution may be obtained using an averaged phase distribution, wherein the averaged distribution is an average of the multiple phase distributions obtained from each of the sequences.

According to one embodiment, said first and second selective RF pulse comprise one of a 90-degree excitation pulse, a train of RF pulses, or a combination thereof.

In another aspect, the invention relates to a method of operating a magnetic resonance imaging system for acquiring magnetic resonance data from a target volume in a subject, the method comprising: using a first MRI sequence containing a first selective RF pulse followed by a first excitation RF pulse to control the MRI system to selectively excite and saturate exchangeable amide protons within a first frequency range in the target volume; irradiate said target volume with the excitation RF pulse that is adapted to excite bulk water protons in the target volume; and acquire first magnetic resonance imaging data from the target volume in response to the first excitation RF pulse; using a second MRI sequence containing a second selective RF pulse followed by a second excitation RF pulse to control the MRI system to selectively excite and saturate the exchangeable amide protons within a second frequency range in the target volume; irradiate said target volume with the second excitation RF pulse that is adapted to excite said bulk water protons; and acquire second magnetic resonance imaging data from said target volume in response to the second excitation RF pulse; wherein the first MRI sequence comprises gradients having first gradient polarities reverse of second gradient polarities of the second MRI sequence; using a third MRI sequence to control the MRI system to acquire un-saturated MRI data of the target volume; generating from the first MRI and second MRI data a respective first phase and second phase distributions; using the first and second phase distributions for determining an electrical conductivity distribution of the target volume; using the first, second and un-saturated MRI data for determining a magnitude distribution of amide proton transfer, APT, corresponding to the transfer of saturation between the amide protons and the water protons.

In another aspect, the invention relates to a computer program product comprising computer executable instructions to perform the method steps of the previous embodiment.

As will be appreciated by one skilled in the art, aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

Aspects of the present invention are described with reference to flowchart illustrations and/or block diagrams of methods, apparatus (systems) and computer program products according to embodiments of the invention. It will be understood that each block or a portion of the blocks of the flowchart, illustrations, and/or block diagrams, can be implemented by computer program instructions in form of computer executable code when applicable. It is further understood that, when not mutually exclusive, combinations of blocks in different flowcharts, illustrations, and/or block diagrams may be combined. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

Any combination of one or more computer readable medium(s) may be utilized. The computer readable medium may be a computer readable signal medium or a computer readable storage medium. A ‘computer-readable storage medium’ as used herein encompasses any tangible storage medium which may store instructions which are executable by a processor of a computing device. The computer-readable storage medium may be referred to as a computer-readable non-transitory storage medium. The computer-readable storage medium may also be referred to as a tangible computer readable medium. In some embodiments, a computer-readable storage medium may also be able to store data which is able to be accessed by the processor of the computing device. Examples of computer-readable storage media include, but are not limited to: a floppy disk, a magnetic hard disk drive, a solid state hard disk, flash memory, a USB thumb drive, Random Access Memory (RAM), Read Only Memory (ROM), an optical disk, a magneto-optical disk, and the register file of the processor. Examples of optical disks include Compact Disks (CD) and Digital Versatile Disks (DVD), for example CD-ROM, CD-RW, CD-R, DVD-ROM, DVD-RW, or DVD-R disks. The term computer readable-storage medium also refers to various types of recording media capable of being accessed by the computer device via a network or communication link. For example a data may be retrieved over a modem, over the internet, or over a local area network. Computer executable code embodied on a computer readable medium may be transmitted using any appropriate medium, including but not limited to wireless, wireline, optical fiber cable, RF, etc., or any suitable combination of the foregoing.

A computer readable signal medium may include a propagated data signal with computer executable code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

‘Computer memory’ or ‘memory’ is an example of a computer-readable storage medium. Computer memory is any memory which is directly accessible to a processor. ‘Computer storage’ or ‘storage’ is a further example of a computer-readable storage medium. Computer storage is any non-volatile computer-readable storage medium. In some embodiments computer storage may also be computer memory or vice versa.

A ‘user interface’ as used herein is an interface which allows a user or operator to interact with a computer or computer system. A ‘user interface’ may also be referred to as a ‘human interface device.’ A user interface may provide information or data to the operator and/or receive information or data from the operator. A user interface may enable input from an operator to be received by the computer and may provide output to the user from the computer. In other words, the user interface may allow an operator to control or manipulate a computer and the interface may allow the computer indicate the effects of the operator's control or manipulation. The display of data or information on a display or a graphical user interface is an example of providing information to an operator. The receiving of data through a keyboard, mouse, trackball, touchpad, pointing stick, graphics tablet, joystick, gamepad, webcam, headset, gear sticks, steering wheel, pedals, wired glove, dance pad, remote control, and accelerometer are all examples of user interface components which enable the receiving of information or data from an operator.

A ‘hardware interface’ as used herein encompasses an interface which enables the processor of a computer system to interact with and/or control an external computing device and/or apparatus. A hardware interface may allow a processor to send control signals or instructions to an external computing device and/or apparatus. A hardware interface may also enable a processor to exchange data with an external computing device and/or apparatus. Examples of a hardware interface include, but are not limited to: a universal serial bus, IEEE 1394 port, parallel port, IEEE 1284 port, serial port, RS-232 port, IEEE-488 port, Bluetooth connection, Wireless local area network connection, TCP/IP connection, Ethernet connection, control voltage interface, MIDI interface, analog input interface, and digital input interface.

A ‘processor’ as used herein encompasses an electronic component which is able to execute a program or machine executable instruction. References to the computing device comprising “a processor” should be interpreted as possibly containing more than one processor or processing core. The processor may for instance be a multi-core processor. A processor may also refer to a collection of processors within a single computer system or distributed amongst multiple computer systems. The term computing device should also be interpreted to possibly refer to a collection or network of computing devices each comprising a processor or processors. Many programs have their instructions performed by multiple processors that may be within the same computing device or which may even be distributed across multiple computing devices.

Magnetic resonance image data is defined herein as being the recorded measurements of radio frequency signals emitted by the subject's/object's atomic spins by the antenna of a Magnetic resonance apparatus during a magnetic resonance imaging scan. A Magnetic Resonance Imaging (MRI) image is defined herein as being the reconstructed two or three dimensional visualization of anatomic data contained within the magnetic resonance imaging data. This visualization can be performed using a computer.

It is understood that one or more of the aforementioned embodiments of the invention may be combined as long as the combined embodiments are not mutually exclusive.

### BRIEF DESCRIPTION OF THE DRAWINGS

In the following preferred embodiments of the invention will be described, by way of example only, and with reference to the drawings in which:

FIG. 1 shows a flowchart of a method for combining APT and EPT;

FIG. 2 illustrates a magnetic resonance imaging system;

FIG. 3 shows graphs of EPT and APT values for different frequency offsets, and

FIG. 4 illustrates pulse sequence time diagrams.

### DETAILED DESCRIPTION OF THE EMBODIMENTS

In the following, like numbered elements in the figures are either similar elements or perform an equivalent function. Elements which have been discussed previously will not necessarily be discussed in later figures if the function is equivalent.

Various structures, systems and devices are schematically depicted in the figures for purposes of explanation only and so as to not obscure the present invention with details that are well known to those skilled in the art. Nevertheless, the attached figures are included to describe and explain illustrative examples of the disclosed subject matter.

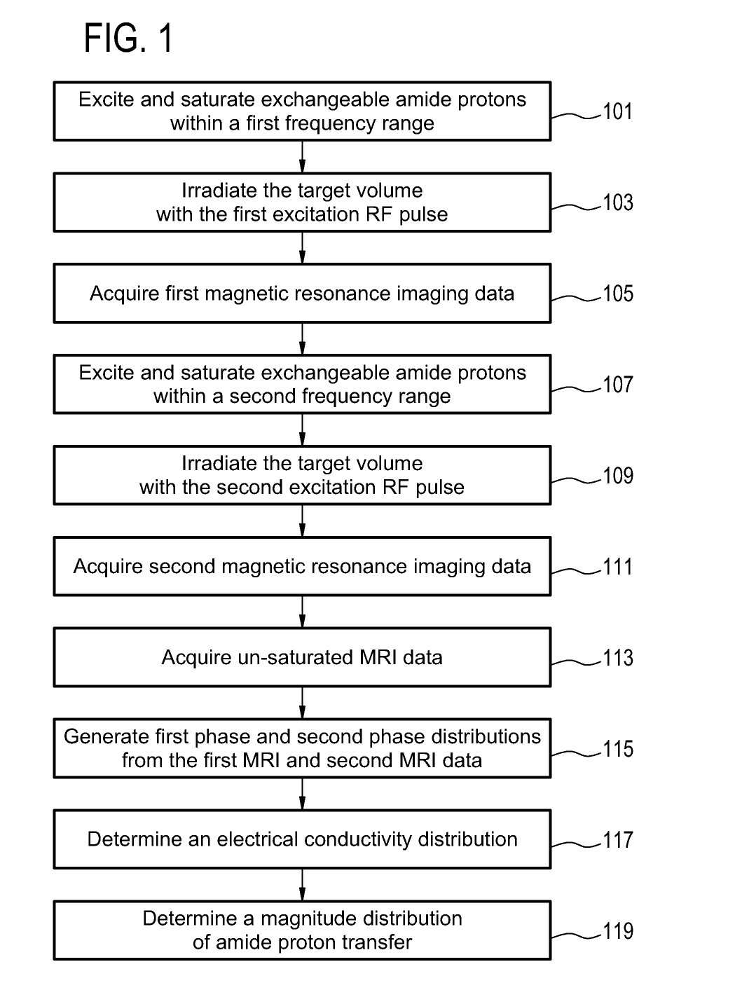

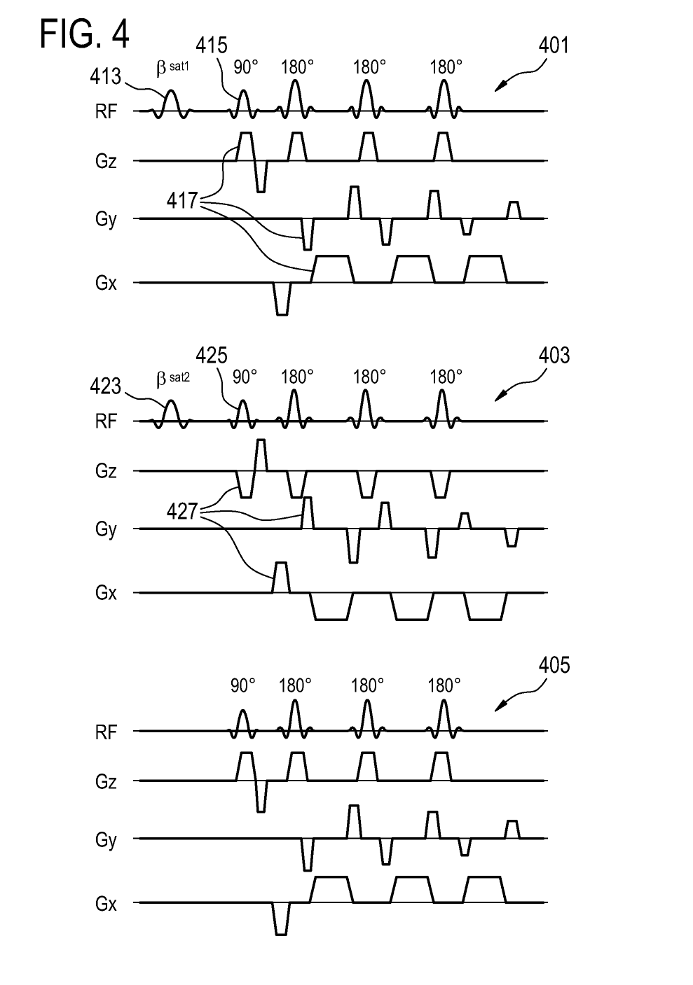

FIG. 1 shows a flow diagram which illustrates a method according to an embodiment of the invention. In step 101, a first MRI sequence containing a first selective saturation RF pulse 413 of FIG. 4 followed by a first excitation RF pulse 415 is used to control an MRI system to selectively excite and saturate exchangeable amide protons within a first frequency range in a target volume of a subject. The first MRI sequence may be a TSE sequence 401. The MRI system may be for example a Philips 3T MRI scanner (Philips Medical Systems, Best, The Netherlands) using a body coil for RF transmission and a 13-channel phased-array coil for reception. For saturation, a multi transmit with 2 channels is used to achieve longer saturation pulses of 2 seconds. In step 103, said target volume is irradiated with the first excitation RF pulse 415 that is adapted to excite bulk water protons in the target volume. In step 105, first magnetic resonance imaging data are acquired from the target volume in response to the first excitation RF pulse 415. The first MRI data may be acquired at a predefined slice with multiple voxels.

In step 107, a second MRI sequence containing a second selective saturation RF pulse 423 followed by a second excitation RF pulse 425 is used to control the MRI system to selectively excite and saturate the exchangeable amide protons within a second frequency range in the target volume. The first and second frequency range are symmetrically shifted on opposite sides of the water resonance frequency. For example, they may be centered around ±3.5 ppm with respect to water resonance frequency. In step 109, said target volume is irradiated with a second excitation RF pulse that is adapted to excite said bulk water protons. In step 111, second magnetic resonance imaging data from said target volume are acquired in response to the second excitation RF pulse 425. The second MRI data may be acquired at the same predefined slice. The first MRI sequence 401 comprises gradients having first gradient polarities 417 reverse of second gradient polarities 427 of the second MRI sequence 403. This is done to compensate unwanted phase contributions arising from gradient switching, which deteriorate the obtained conductivity distribution. The first and second selective RF pulses 413 and 423 may be followed by separate spoiler gradients (not shown in FIG. 4) which can be placed with certain time offsets with respect to the previous (i.e. saturation pulse) and next RF excitation pulse.

In step 113, a third MRI sequence 405 is used to control the MRI system to acquire un-saturated MRI data of the target volume. The third MRI sequence comprises a TSE sequence without RF saturation pulse applied and may have the same TR.

In step 115, first phase and second phase distributions are generated respectively from the first MRI and second MRI data. The generated phase may be the measured phase of the MRI signal. The phase distribution may be a distribution of measured phase values in the multiple voxels.

In step 117, the first and second phase distributions are used for determining an electrical conductivity distribution of the target volume. The electrical conductivity estimation requires a determination of the B1+ phase which is the phase of the positively rotating component of the RF transmit field (i.e., its “active” component responsible for spin excitation). The B1+ phase φ_{B1} may be determined from the measured phase (φ±) using the relation φ_{B1}=0.5φ±, which takes into account that the measured phase contains not only the phase contribution from RF transmission but also the (approximately identical) phase contribution from RF reception.

The computation of the B1+ phase may be performed on a voxel-by-voxel basis across the first and second phase distributions. For example, for each voxel a mean value of the first measured phase and second measured phase in that voxel is calculated and the B1+ phase is deduced from the mean phase value. In another example, a B1+ phase is derived for each voxel using the first and second distribution for obtaining first and second B1+ phase values each associated with corresponding measured phase distribution. The required B1+ phase value may then be obtained as a mean value of the first and second B1+ phase values. The electrical conductivity may then be determined on a voxel by voxel basis as well using the following formula (cf. Katscher U et al., IEEE Trans Med Imag 28 (2009) 1365)

$$σ = \frac{{Δϕ}_{B 1}}{μω}$$

where Δ the Laplacian operator, μ the magnetic permeability, and ω the Larmor frequency. The Laplacian is based on the second derivatives ∂² and can be calculated numerically, e.g., via

∂ₓ²φ_{B1}(xₙ)˜φ_{B1}(xₙ₋₁)−2φ_{B1}(xₙ)+φ_{B1}(xₙ₊₁)

for the voxel with spatial index n.

In step 119, the first, second and un-saturated MRI data are used for determining a magnitude distribution of amide proton transfer, APT, corresponding to the transfer of saturation between the amide protons and the water protons. The magnitude of amide proton transfer effect may be determined using an amide proton transfer ratio MTR at the first frequency range and at the second frequency range and may be defined (on a voxel by voxel basis) as follows:

MTR_{asym}=(S(−offset)−S(+offset))/S₀

which Sₛₐₜ(−offset) and Sₛₐₜ(+offset) are the signal amplitudes obtained from the first MRI data and second MRI data respectively. S₀ is the signal amplitude obtained from the third MRI data without selective saturation RF pulse. In order to correct for the artifacts that may be caused by B0 inhomogeneity extra MRI data may be acquired for extra offsets around the ±offset (e.g. ±3.5 ppm) For example, four offsets (±3, and ±4 ppm), may be used to acquire additional MRI data using MRI sequences having mutually inverted gradient polarities, The MTRasym may be calculated using the signals at ±3.5 ppm. In case of B0 inhomogeneity, the whole spectrum may be shifted depending on the B0 value, in the sense that the measurement may be performed at different offset than the desired one e.g. ±3.5 ppm. With the additional offset frequencies on each side and a B0 map, the actual signal at ±3.5 ppm may be deduced and then used to compute the MTRasym.

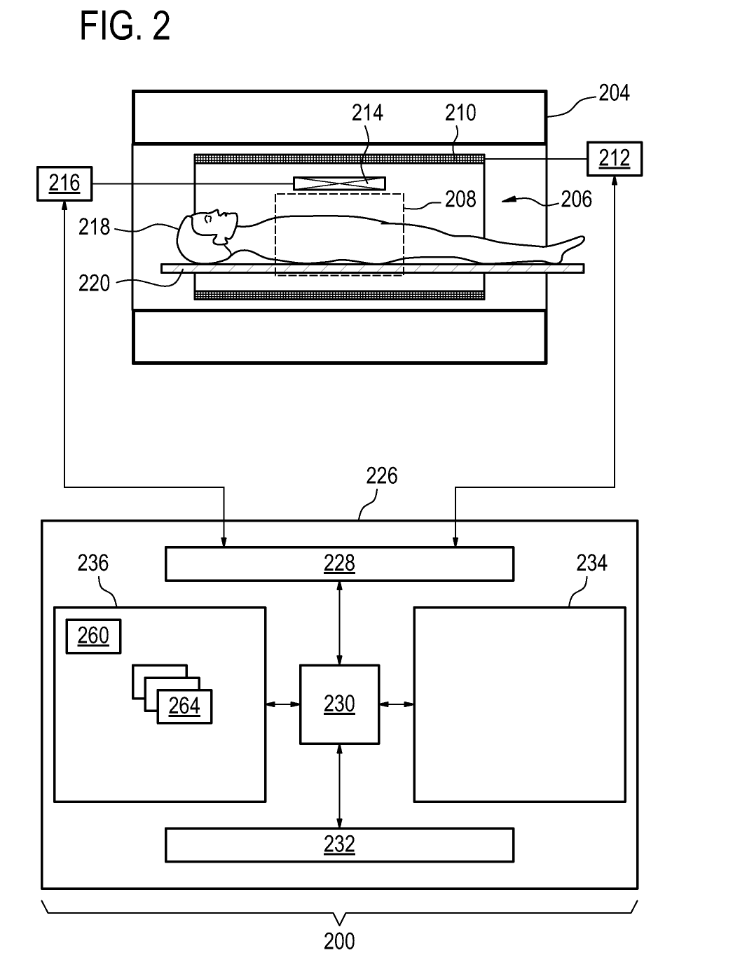

FIG. 2 illustrates an example of a magnetic resonance imaging system 200. The magnetic resonance imaging system 200 comprises a magnet 104. The magnet 204 is a superconducting cylindrical type magnet 200 with a bore 206 through it. The use of different types of magnets is also possible for instance it is also possible to use both a split cylindrical magnet and a so called open magnet. A split cylindrical magnet is similar to a standard cylindrical magnet, except that the cryostat has been split into two sections to allow access to the iso-plane of the magnet, such magnets may for instance be used in conjunction with charged particle beam therapy. An open magnet has two magnet sections, one above the other with a space in-between that is large enough to receive a subject 218, the arrangement of the two sections area similar to that of a Helmholtz coil. Open magnets are popular, because the subject is less confined. Inside the cryostat of the cylindrical magnet there is a collection of superconducting coils. Within the bore 206 of the cylindrical magnet 204 there is an imaging zone 208 where the magnetic field is strong and uniform enough to perform magnetic resonance imaging.

Within the bore 206 of the magnet there is also a set of magnetic field gradient coils 210 which is used for acquisition of magnetic resonance data to spatially encode magnetic spins of a target volume within the imaging zone 208 of the magnet 204. The magnetic field gradient coils 210 are connected to a magnetic field gradient coil power supply 212. The magnetic field gradient coils 210 are intended to be representative. Typically magnetic field gradient coils 210 contain three separate sets of coils for spatially encoding in three orthogonal spatial directions. A magnetic field gradient power supply supplies current to the magnetic field gradient coils. The current supplied to the magnetic field gradient coils 210 is controlled as a function of time and may be ramped or pulsed.

Adjacent to the imaging zone 208 is a radio-frequency coil 214 for manipulating the orientations of magnetic spins within the imaging zone 208 and for receiving radio transmissions from spins also within the imaging zone 208. The radio frequency antenna may contain multiple coil elements. The radio frequency antenna may also be referred to as a channel or antenna. The radio-frequency coil 214 is connected to a radio frequency transceiver 216. The radio-frequency coil 214 and radio frequency transceiver 216 may be replaced by separate transmit and receive coils and a separate transmitter and receiver. It is understood that the radio-frequency coil 214 and the radio frequency transceiver 216 are representative. The radio-frequency coil 214 is intended to also represent a dedicated transmit antenna and a dedicated receive antenna. Likewise the transceiver 216 may also represent a separate transmitter and receivers.

The magnetic field gradient coil power supply 212 and the transceiver 216 are connected to a hardware interface 228 of computer system 226. The computer system 226 further comprises a processor 230. The processor 230 is connected to the hardware interface 228, a user interface 232, a computer storage 134, and computer memory 236.

The computer memory 236 is shown as containing a control module 260. The control module 260 contains computer-executable code which enables the processor 230 to control the operation and function of the magnetic resonance imaging system 200. It also enables the basic operations of the magnetic resonance imaging system 200 such as the acquisition of magnetic resonance data. The computer memory 236 is further shown as containing a program/utility 264 having a set of program modules that contain computer-executable code which enables the processor 230 to carry out the functions and/or methodologies of embodiments of the invention as described herein e.g. with reference to FIG. 1.

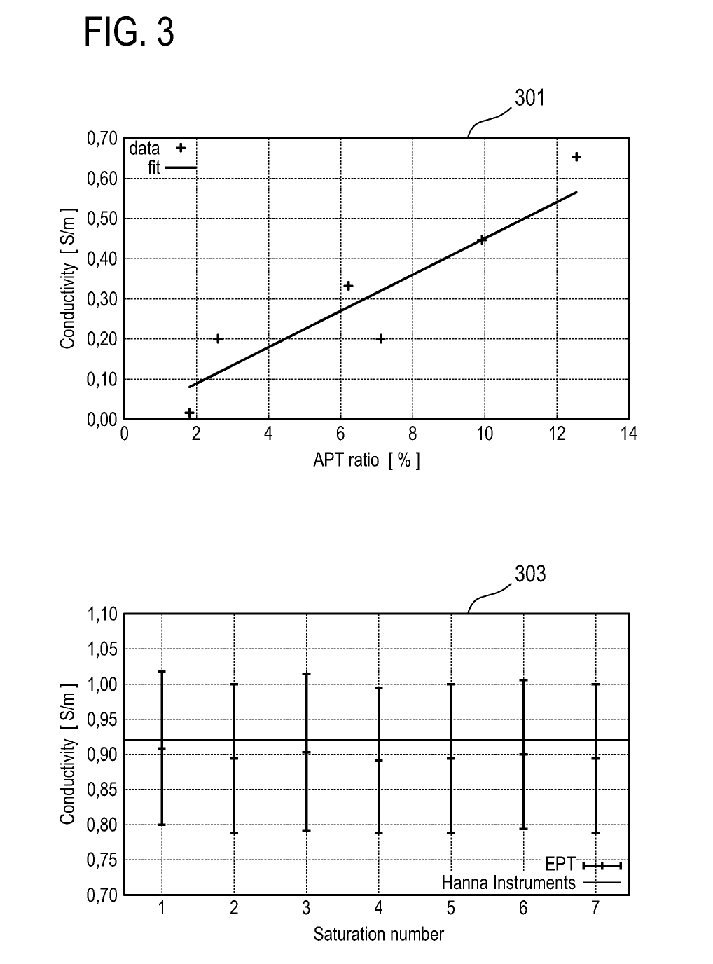

FIG. 3 shows the results of the present method on a phantom prepared with six vials (30 ml) filled with a mixture pasteurized chicken egg-white (10% protein), water and Magnevist (Bayer Healthcare), with protein concentrations of 0.6% up to 7% which were adjusted to equal T1 relaxation. The phantom may be for example placed instead of subject 218 inside the MRI system 100.

Imaging parameters for the phantom are determined for a 3 Tesla scanner. The images were acquired with a Philips Achieva 3T system. For saturation, an off-resonance RF pulse was applied for 3 s at a power of 3 muT by a 3D TSE sequence with TE/TR=6/17440 ms, 330 mm*300 mm FOV, and a slice in sagittal orientation with slice thickness=5 mm and with 0.9×0.9×5 mm³ voxel size.

High-SNR APT-weighted (APTw) images (determined using the above asymmetric equation) were acquired using six frequency offsets (namely, ±3, ±3.5, and ±4 ppm). For this scan, one unsaturated image (without RF saturation, same TR) was acquired for normalization. One image was acquired per offset. The effects of the saturation transfer of exchangeable protons to water were subsequently identified by asymmetry analysis as described above.

The plot 301 of FIG. 3 shows reconstruction results of the six different vials comparing EPT and APT ratio values. The conductivity is increasing with the APT ratio, i.e. with the egg-white concentration as expected. Data points are averages over all voxels belonging to a certain vial.

To confirm that the frequency of the saturation pulse does not influence the measured phase (and thus the reconstructed electrical conductivity), the described sequence was further applied to a homogeneous egg-white phantom (size˜500 mL). The reconstructed conductivities 303 do not show any dependence on the saturation frequencies as expected, which justify the proposed averaging method over multiple MRI data obtained with different sequence having inverted polarities. Besides, they are consistent with the independent measurement by an external device (HI8733, Hanna Instruments).

### LIST OF REFERENCE NUMERALS

200 magnetic resonance imaging system
204 magnet
206 bore of magnet
208 imaging zone
210 magnetic field gradient coils
212 magnetic field gradient coil power supply
214 radio-frequency coil
216 transceiver
218 subject
220 subject support
226 computer system
228 hardware interface
230 processor
232 user interface
234 computer storage
236 computer memory
260 control module
264 program
301 graph
303 graph
401-405 pulse sequences
413, 423 saturation pulse
415, 425 excitation pulse
417, 427 gradient pulse.

1. A magnetic resonance imaging, system for acquiring magnetic resonance data from a target volume in a subject, the magnetic resonance imaging system comprising a memory for storing machine executable instructions; and a processor for controlling the magnetic resonance imaging system, wherein execution of the machine executable instructions causes the processor to:
use a first magnetic resonance imaging sequence containing a first selective radio frequency pulse followed by a first excitation radio frequency pulse to control the magnetic resonance imaging system to selectively excite and saturate exchangeable endogeneous nuclei causing the CEST effect within a first frequency range in the target volume; irradiate said target volume with the first excitation radio frequency pulse that is adapted to excite bulk water protons in the target volume; and acquire first magnetic resonance imaging data from the target volume in response to the first excitation radio frequency pulse;
use a second magnetic resonance imaging sequence containing a second selective radio frequency pulse followed by a second excitation radio frequency pulse to control the magnetic resonance imaging system to selectively excite and saturate the exchangeable endogeneous nuclei causing the CEST effect, within a second frequency range in the target volume; irradiate said target volume with the second excitation radio frequency pulse that is adapted to excite said bulk water protons; and acquire second magnetic resonance imaging data from said target volume in response to the second excitation radio frequency pulse;
wherein the first magnetic resonance imaging sequence comprises gradients having first gradient polarities reverse of second gradient polarities of the second magnetic resonance imaging sequence;
use a third magnetic resonance imaging sequence to control the magnetic resonance imaging system to acquire un-saturated magnetic resonance imaging data of the target volume;
generate from the first magnetic resonance imaging and second magnetic resonance imaging data a respective first phase and second phase distributions;
use the first and second phase distributions for determining an electrical conductivity distribution of the target volume;
use the first, second and un-saturated magnetic resonance imaging data for determining a magnitude distribution of amide proton transfer, APT, corresponding to the transfer of saturation between the amide protons and the water protons.

2. A magnetic resonance imaging, magnetic resonance imaging, system as claimed in claim 1,
wherein the first magnetic resonance imaging sequence containing a first selective radio frequency pulse followed by a first excitation radio frequency pulse to control the magnetic resonance imaging system are adapted to selectively excite and saturate exchangeable amide protons within a first frequency range in the target volume; irradiate said target volume with the first excitation radio frequency pulse that is adapted to excite bulk water protons in the target volume; and acquire first magnetic resonance imaging data from the target volume in response to the first excitation radio frequency pulse
wherein the second magnetic resonance imaging sequence containing a second selective radio frequency pulse followed by the second excitation radio frequency pulse to control the magnetic resonance imaging system are adapted to selectively excite and saturate the exchangeable amide protons within a second frequency range in the target volume; irradiate said target volume with the second excitation radio frequency pulse that is adapted to excite said bulk water protons; and acquire second magnetic resonance imaging data from said target volume in response to the second excitation radio frequency pulse;
wherein the first, second and un-saturated magnetic resonance imaging data determine a magnitude distribution of amide proton transfer, APT, corresponding to the transfer of saturation between the amide protons and the water protons.

3. The magnetic resonance imaging system of claim 1, wherein the determination of the electrical conductivity distribution comprises averaging the first phase distribution and second phase distributions to obtain an averaged phase distribution; determining from the averaged phase distribution a B1 field phase distribution to determine the electrical conductivity distribution.

4. The magnetic resonance imaging system of claim 1, wherein the determination of the electrical conductivity distribution comprises generating from the un-saturated magnetic resonance imaging data a third phase distribution; averaging the first, second and third phase distributions to obtain an averaged phase distribution; determining from the averaged phase distribution a B1 field phase distribution to determine the electrical conductivity distribution.

5. The magnetic resonance imaging system of claim 1, wherein the magnetic resonance imaging system further comprises multiple radio frequency coils for parallel data acquisition, the multiple radio frequency coils having a spatial sensitivity map determined using pre-acquired k-space data, wherein the execution of the machine executable instructions further causes the processor to reconstruct image data from the acquired first, second and third magnetic resonance imaging data using the sensitivity map.

6. The magnetic resonance imaging system of claim 1, wherein the first magnetic resonance imaging data and second magnetic resonance imaging data are acquired using a predefined first and second k-space region respectively, wherein the second k-space region is part of the first k-space region.

7. The magnetic resonance imaging system of claim 6, wherein the second k-space region is the central region of k-space.

8. The magnetic resonance imaging system of claim 1, wherein the first and second frequency range are symmetrically shifted on opposite sides of the water resonance frequency.

9. The magnetic resonance imaging system of claim 1, wherein the center of first frequency range is set to a resonance frequency of the amide protons.

10. The magnetic resonance imaging system of claim 1, wherein the first gradient polarities comprise slice-selective, read, and phase encoding gradient polarities.

11. The magnetic resonance imaging system of claim 1, wherein the magnitude of amide proton transfer is determined using an amide proton transfer ratio MTR at the first frequency range and at the second frequency range.

12. The magnetic resonance imaging system of claim 1, wherein the first and second magnetic resonance imaging data form a first pair of magnetic resonance imaging data, wherein the execution of the machine executable instructions further causes the processor to repeat,
using a first magnetic resonance imaging sequence containing a first selective radio frequency pulse followed by a first excitation radio frequency pulse to control the magnetic resonance imaging system to selectively excite and saturate exchangeable exogenous nuclei causing the CEST effect within a first frequency range in the target volume; irradiate said target volume with the first excitation radio frequency pulse that is adapted to excite bulk water protons in the target volume; and acquire first magnetic resonance imaging data from the target volume in response to the first excitation radio frequency pulse;
using a second magnetic resonance imaging sequence containing a second selective radio frequency pulse followed by a second excitation radio frequency pulse to control the magnetic resonance imaging system to selectively excite and saturate the exchangeable exogenous nuclei causing the CEST effect, within a second frequency range in the target volume; irradiate said target volume with the second excitation radio frequency pulse that is adapted to excite said bulk water protons; and acquire second magnetic resonance imaging data from said target volume in response to the second excitation radio frequency pulse;
the repeated steps acquiring a plurality of pairs of magnetic resonance imaging data using pulse sequences having mutually inverted gradient polarities, wherein the determination of the magnitude of amide proton transfer, APT, comprises determining for each pair a respective APT distribution, and averaging the determined APT distributions for obtaining an averaged APT distribution.

13. The magnetic resonance imaging system of claim 1, wherein said first and said second selective radio frequency pulse comprise one of a 90-degree excitation pulse, a train of radio frequency pulses, or a combination thereof.

14. A Method of operating a magnetic resonance imaging system for acquiring magnetic resonance data from a target volume in a subject, the method comprising:
using a first magnetic resonance imaging sequence containing a first selective radio frequency pulse followed by a first excitation radio frequency pulse to control the magnetic resonance imaging system to selectively to selectively excite and saturate exchangeable endogeneous nuclei causing the CEST effect within a first frequency range in the target volume; and acquire first magnetic resonance imaging data from the target volume in response to the first excitation radio frequency pulse;
using a second magnetic resonance imaging sequence containing a second selective radio frequency pulse followed by a second excitation radio frequency pulse to control the magnetic resonance imaging system to selectively excite and saturate exchangeable endogeneous nuclei causing the CEST effect within a first frequency range in the target volume; irradiate said target volume with the second excitation radio frequency pulse that is adapted to excite said bulk water protons; and acquire second magnetic resonance imaging data from said target volume in response to the second excitation radio frequency pulse;
wherein the first magnetic resonance imaging sequence comprises gradients having first gradient polarities reverse of second gradient polarities of the second magnetic resonance imaging sequence;
using a third magnetic resonance imaging sequence to control the magnetic resonance imaging system to acquire un-saturated magnetic resonance imaging data of the target volume;
generating from the first magnetic resonance imaging and the second magnetic resonance imaging data a respective first phase and second phase distributions;
using the first and second phase distributions for determining an electrical conductivity distribution of the target volume;
using the first, the second and the un-saturated magnetic resonance imaging data for determining a magnitude distribution of amide proton transfer, APT, corresponding to the transfer of saturation between the amide protons and the water protons.

15. A computer program product comprising computer executable instructions to perform the method steps claim 14.

16. A magnetic resonance imaging, system for acquiring magnetic resonance data from a target volume in a subject, the magnetic resonance imaging system comprising a memory for storing machine executable instructions; and a processor for controlling the magnetic resonance imaging system, wherein execution of the machine executable instructions causes the processor to:
use a first magnetic resonance imaging sequence containing a first selective radio frequency pulse followed by a first excitation radio frequency pulse to control the magnetic resonance imaging system to selectively excite and saturate exchangeable exogenous nuclei causing the CEST effect within a first frequency range in the target volume; irradiate said target volume with the first excitation radio frequency pulse that is adapted to excite bulk water protons in the target volume; and acquire first magnetic resonance imaging data from the target volume in response to the first excitation radio frequency pulse;
use a second magnetic resonance imaging sequence containing a second selective radio frequency pulse followed by a second excitation radio frequency pulse to control the magnetic resonance imaging system to selectively excite and saturate the exchangeable exogenous nuclei causing the CEST effect, within a second frequency range in the target volume; irradiate said target volume with the second excitation radio frequency pulse that is adapted to excite said bulk water protons; and acquire second magnetic resonance imaging data from said target volume in response to the second excitation radio frequency pulse;
wherein the first magnetic resonance imaging sequence comprises gradients having first gradient polarities reverse of second gradient polarities of the second magnetic resonance imaging sequence;
use a third magnetic resonance imaging sequence to control the magnetic resonance imaging system to acquire un-saturated magnetic resonance imaging data of the target volume;
generate from the first magnetic resonance imaging and second magnetic resonance imaging data a respective first phase and second phase distributions;
use the first and second phase distributions for determining an electrical conductivity distribution of the target volume;
use the first, second and un-saturated magnetic resonance imaging data for determining a magnitude distribution of amide proton transfer, APT, corresponding to the transfer of saturation between the amide protons and the water protons.
